(19) United States
(12) Patent Application Publication
(10) Pub. No.: US 2015/0313005 A1
(43) Pub. Date: Oct. 29, 2015

(54) PRINTED CIRCUIT BOARD

(71) Applicants: Masashi TAKABATAKE, Kanagawa (JP); Kenji KASHIWAGI, Kanagawa (JP)

(72) Inventors: Masashi TAKABATAKE, Kanagawa (JP); Kenji KASHIWAGI, Kanagawa (JP)

(73) Assignee: Hitachi, Ltd.

(21) Appl. No.: 14/406,913

(22) PCT Filed: Jun. 15, 2012
(86) PCT No.: PCT/JP2012/065406

§ 371 Date: May 22, 2015

(51) Int. Cl. H05K 1/02; H05K 1/11

(52) U.S. Cl. CPC H05K 1/0213; H05K 1/111; H05K 2201/0776; H05K 2201/09372

(57) ABSTRACT

[Object] There is suggested a printed circuit board capable of realizing impedance matching by securing joint reliability between signal pins of a surface mount connector and signal pin pads and preventing the reduction of impedance of signal pin pads while minimizing the reduction of a wirable area.

[Solution] A printed circuit board equipped with a signal pin pad, which is soldered to a signal pin from a surface mount connector, and a ground layer located as a lower layer below the signal pin pad; wherein a fillet is formed around a joint area between the signal pin and the signal pin pad after soldering; wherein a cut-out portion is provided in the signal pin pad within a joint area with the signal pin; and wherein the size of the cut-out portion is set within the range of being completely covered within the joint area with the signal pin based on size tolerance of the signal pin, fabrication tolerance of the printed circuit board, and mount position tolerance of the surface mount connector.

### TECHNICAL FIELD

The present invention relates to a printed circuit board. Particularly, the invention is suited for use in a printed circuit board designed to realize impedance matching between signal pins of a surface mount connector and signal pin pads, which are connected to the signal pins, on the printed circuit board.

### BACKGROUND ART

Conventionally, when a surface mount connector is connected to a printed circuit board and an attempt is made to transmit a high-speed signal from the surface mount connector via the printed circuit board, there are problems of occurrence of noises and reflections and degradation of signal quality.

Specifically speaking, capacitive coupling takes place between signal pin pads, which are connected to signal pins of the surface mount connector, on the printed circuit board and a ground layer provided directly below the signal pin pads and this capacitive coupling causes an impedance reduction of the signal pin pads. If the impedance of the signal pin pads reduces, a reflection is generated due to impedance unmatching between the signal pins of the surface mount connector and the signal pin pads connected to the signal pins. As a result, the signal quality degrades.

Since previously a transmission speed was comparatively low, rise time/fall time of a transmission signal was larger than electrical length of the signal pin pad portion. Therefore, even if the impedance of a signal pin pads reduces and a reflection is generated due to the impedance unmatching, its reflection amount is substantially small and has a low impact on the signal quality.

However, in recent years, the rise/fall time of the transmission signal has become shorter than the electrical length of the signal pin pad portion because of an increase of the transmission speed. So, if the impedance of the signal pin pads reduces, the reflection amount of the reflection generated due to the impedance unmatching increases. As a result, the impact on the signal quality becomes significant.

Consequently, various techniques capable of preventing the reduction of the impedance of the signal pin pads even in a case of a high transmission speed are examined and disclosed.

For example, Patent Literature 1 discloses a technique that attempts to realize impedance matching by chipping off a central portion of a signal pin pad to divide the signal pin pad into two pieces so that a joint portion between a signal pin of a surface mount connector and the signal pin pad will be only both ends of the signal pin, and reducing the area of the signal pin pad opposite a ground layer directly below the signal pin pad, thereby reducing the capacitive coupling between the signal pin pad and the ground layer and preventing the reduction of the impedance of the signal pin pad. Incidentally, the signal pin and the signal pin pad are soldered and the central portion of the signal pin after soldering becomes bulged without forming a fillet.

Furthermore, Patent Literature 2 discloses a technique that attempts to realize impedance matching by chipping off one end of a signal pin of a surface mount connector to reduce the area of the signal pin in contact with a signal pin pad, and downsizing the signal pin pad accordingly to reduce the area of the signal pin pad opposite a ground layer directly below the signal pin pad, thereby reducing the capacitive coupling between the signal pin pad and the ground layer and preventing the reduction of the impedance of the signal pin pad. There is also disclosed a technique that attempts to realize impedance matching by also chipping off the ground layer directly below the signal pin pad to reduce the ground layer, which is opposite the signal pin pad and located directly below the signal pin pad, reducing the capacitive coupling between the signal pin pad and the ground layer, and preventing the reduction of the impedance of the signal pin pad.

### CITATION LIST

### Patent Literature

[Patent Literature 1] Japanese Patent Application Laid-Open (Kokai) Publication No. 2009-141170

[Patent Literature 2] Japanese Patent Application Laid-Open (Kokai) Publication No. 2011-119123

### SUMMARY OF INVENTION

### Problems to be Solved by the Invention

However, regarding the technique disclosed in Patent Literature 1, the central portion of the signal pin pad, which is to be connected to the signal pin of the surface mount connector, on the printed circuit board is chipped off. If the signal pin pad is not chipped off, the central portion of the soldered signal pin is chipped off. So, an area where fillets are formed is reduced as compared to the case in which the relevant portions are soldered. Therefore, a problem of degradation of joint reliability arises at a joint portion between the signal pin of the surface mount connector and the signal pin pad on the printed circuit board.

Moreover, regarding the technique disclosed in Patent Literature 2, one end of the signal pin is chipped off and the size of the signal pin pad to be connected to the signal pin is reduced accordingly. So, a joint area between the signal pin and the signal pin pad is reduced as compared to the case in which the signal pin and the signal pin pad are not chipped off. Therefore, an area where the fillet is formed is reduced as compared to the case in which the relevant portions are soldered. As a result, the problem of degradation of joint reliability arises at the joint portion between the signal pin of the surface mount connector and the signal pin pad on the printed circuit board.

Furthermore, when the ground layer directly below the signal pin pad is chipped off and if a signal line is located directly below the chipped-off ground layer, a return current of the signal cannot be secured and the signal quality will degrade. Therefore, since the signal line cannot be located directly below the position of the chipped-off part of the ground layer, a problem of reduction of a wirable area occurs.

The present invention was devised in consideration of the above-described circumstances and aims at proposing a printed circuit board capable of realizing impedance matching by securing joint reliability and preventing the impedance reduction of the signal pin pads.

### Means for Solving the Problems

In order to solve the above-described problems, the present invention provides a printed circuit board including a signal pin pad, which is soldered to a signal pin from a surface mount connector, and a ground layer located as a lower layer below the signal pin pad, wherein a fillet is formed around a joint area between the signal pin and the signal pin pad after soldering; a cut-out portion is provided in the joint area of the signal pin pad connected with the signal pin; the size of the cut-out portion is set within the range of being completely covered within the joint area with the signal pin, based on size tolerance of the signal pin, fabrication tolerance of the printed circuit board, and mount position tolerance of the surface mount connector; and the ground layer is chipped off as necessary and a chipped-off area is made as small as possible.

### Advantageous Effects of Invention

According to the present invention, it is possible to realize impedance matching by securing joint reliability and preventing reduction of the impedance of the signal pin pads.

### BRIEF DESCRIPTION OF DRAWINGS

FIG. 1 is an appearance configuration diagram of a printed circuit board.

FIG. 2 is a schematic configuration diagram of cross-section surface A of the printed circuit board.

FIG. 3 is a schematic configuration diagram of cross-section surface A of a conventional printed circuit board.

FIG. 4 is a schematic configuration diagram of a top surface of the printed circuit board.

FIG. 5 is a schematic configuration diagram of a top surface of the conventional printed circuit board.

FIG. 6 is a diagram illustrating simulation results.

FIG. 7 is a schematic configuration diagram of cross-section surface A of a printed circuit board according to a second embodiment.

FIG. 8 is a schematic configuration diagram of a top surface of the printed circuit board according to the second embodiment.

FIG. 9 is a diagram illustrating simulation results according to the second embodiment.

FIG. 10 is a diagram illustrating the simulation results according to the second embodiment.

FIG. 11 is a schematic configuration diagram of cross-section surface A of a printed circuit board according to a third embodiment.

FIG. 12 is a schematic configuration diagram of a top surface of the printed circuit board according to the third embodiment.

FIG. 13 is a diagram illustrating simulation results according to the second and third embodiments.

FIG. 14 is diagram illustrating simulation results according to the second and third embodiments.

### MODE FOR CARRYING OUT THE INVENTION

An embodiment of the present invention will be explained below in detail with reference to drawings.

### (1) First Embodiment

### (1-1) Appearance Configuration of Printed Circuit Board

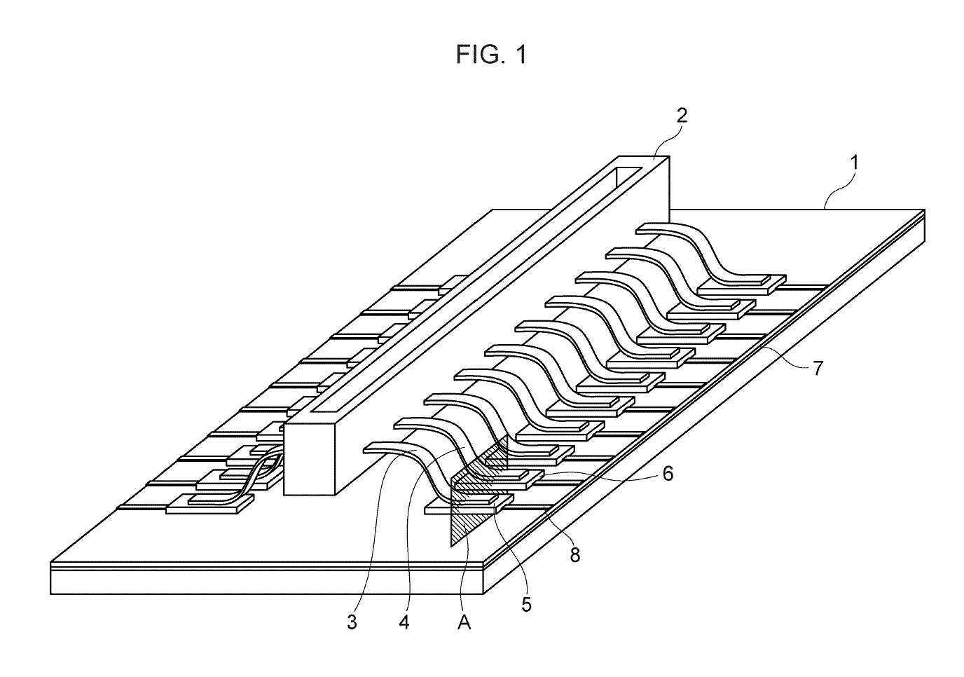

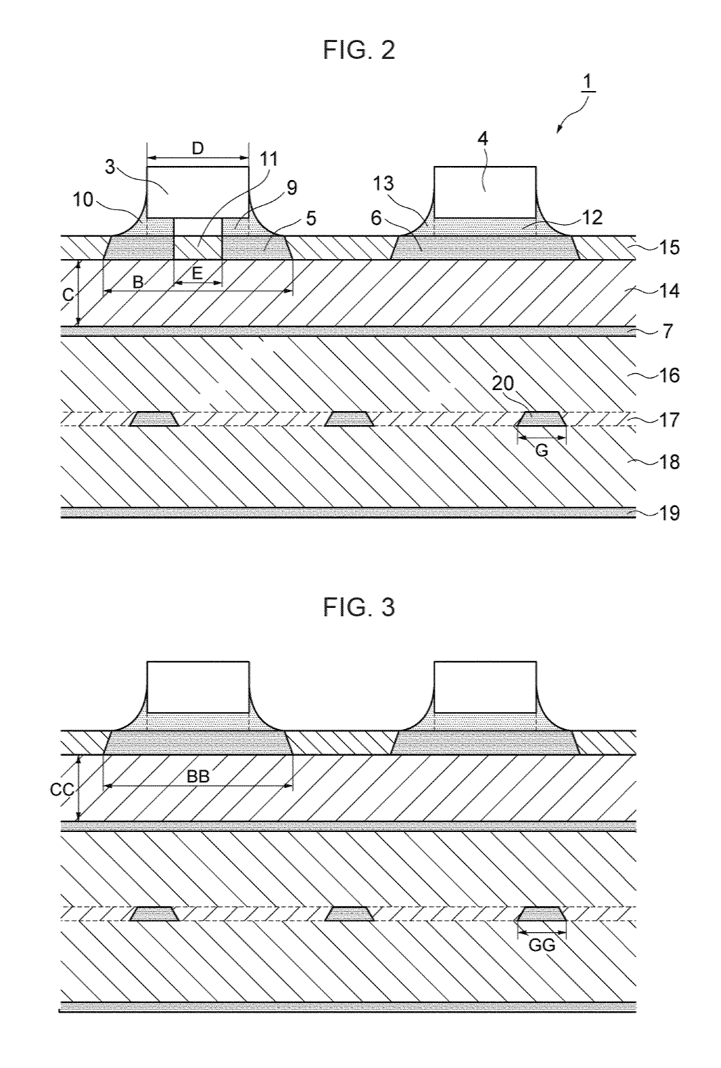

FIG. 1 shows an appearance configuration of a printed circuit board 1. The printed circuit board 1 and a surface mount connector 2 are connected by being soldered to each other. With the printed circuit board 1, ends of signal pins 3 and ground pins 4 from the surface mount connector 2 are connected to signal pin pads 5 and ground pin pads 6 on the printed circuit board 1. Furthermore, a ground layer 7 is located directly below the signal pin pads 5 and the ground pin pads 6. A signal line 8 is also located as a lower layer below the signal pin pads 5 and the ground pin pads 6. Cross-section surface A is a cross-section surface including the signal pin 3, the ground pin 4, the signal pin pad 5, the ground pin pad 6, and the ground layer 7 and its details will be explained later (see FIG. 2).

Incidentally, a conventional printed circuit board has a problem of generation of capacitive coupling between the signal pin pads and the ground layer located directly below the signal pin pads, thereby causing the reduction of impedance of the signal pin pads. When the impedance of the signal pin pads reduces, a reflection is caused due to impedance unmatching between the signal pins and the signal pin pads, which results in degradation of signal quality. According to the present invention, this impedance reduction of the signal pin pads can be prevented by adopting the configuration described later.

### (1-2) Cross-Section Surface Configuration of Printed Circuit Board

FIG. 2 shows a schematic configuration of the cross-section surface A of the printed circuit board 1. Referring to the cross-section surface A the signal pin 3 is connected to the signal pin pad 5 via a soldered joint portion 9 and a fillet 10. A cut-out portion 11 is provided at a central part of the signal pin pad 5.

Moreover, the ground pin 4 is connected to the ground pin pad 6 via a soldered joint portion 12 and a fillet 13. Incidentally, a cut-out portion is not provided, or may be provided, at a central part of the ground pin pad 6.

Furthermore, a surface insulating layer 14 is placed as an upper layer above the ground layer 7 and a resist layer 15 is placed as an upper layer above the surface insulating layer 14. On the other hand, an intermediate insulating layer 16 is placed as a lower layer below the ground layer 7, a signal layer 17 is placed as a lower layer below the intermediate insulating layer 16, a second intermediate insulating layer 18 is placed as a louver layer below the signal layer 17, and a second ground layer 19 is placed as a lower layer below the intermediate insulating layer 18. A signal line 20 is located in the signal layer 17.

Furthermore, as illustrated in FIG. 2, G represents the width of the signal line 20, B represents the width of the signal pin pad 5, C represents the thickness of the surface insulating layer 14, D represents the width of the signal pin 3, and E represents the width of the cut-out portion 11.

Under this circumstance, the size (width and length) of the cut-out portion 11 according to this embodiment is set within the range of being completely covered by the signal pin 3 even in consideration of size tolerance of the signal pin 3, fabrication tolerance M of the printed circuit board 1, and mount position tolerance N of the surface mount connector 2. If the cut-out portion 11 is set within the range of being completely covered by the signal pin 3 in this way, the fillet 10 can be formed around the joint portion between the signal pin 3 and the signal pin pad 5 which are soldered to each other even if the cut-out portion 11 is provided in the signal pin pad 5; and, therefore, joint reliability can be secured.

When L1 represents size tolerance of the signal pin 3 in its widthwise direction, M1 represents fabrication tolerance of the printed circuit board 1 in its widthwise direction, and N1 represents mount position tolerance of the surface mount connector 2 in its widthwise direction, variations of tolerances are usually normal distribution and the sum of the tolerances can be expressed by the sum of squares of tolerance elements. So, the width E of the cut-out portion 11 according to this embodiment is set within the range satisfying the following Formula (1).

[Math. 1]

E<D−\sqrt{L1²+M1²+N1²} (1)

By setting the width E of the cut-out portion 11 within the range satisfying the above Formula (1), the fillet 10 can be formed in the same manner as in the conventional case around the joint portion between the signal pin 3 and the signal pin pad 5 which have being soldered. Joint reliability with aged degradation of the soldered joint portion 9 which is connected by soldering is decided depending on the area where the fillet 10 is formed. Since the area where the fillet 10 is formed is secured in this embodiment in the same manner as in the conventional case, the same degree of joint reliability between the signal pin 3 and the signal pin pad 5 as that of the conventional case can be secured.

FIG. 3 shows a schematic configuration of cross-section surface A of a conventional printed circuit board as compared to the schematic configuration of the cross-section surface A as illustrated in FIG. 2. The cut-out portion 11 according to this embodiment is not provided in the conventional printed circuit board. So, the impedance of the signal pin pads decreases due to capacitive coupling between the signal pin pads and the ground layer. For example, when the width BB of the signal pin pad is 0.7 mm, the thickness CC of the surface insulating layer is 0.1 to 0.15 mm, and the width GG of the signal line is 0.1 to 0.2 mm, the impedance of the signal pin pad decreases to a half or less as compared to the signal line. As a result, a problem of signal quality degradation occurs due to impedance un matching between the signal pins and the signal pin pads.

### (1-3) Top Surface Configuration of Printed Circuit Board

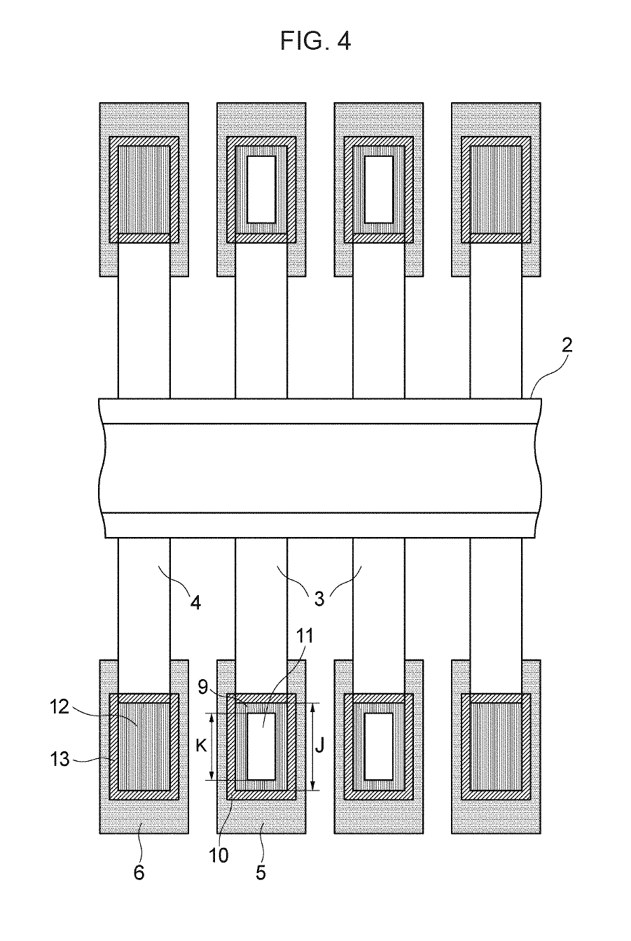

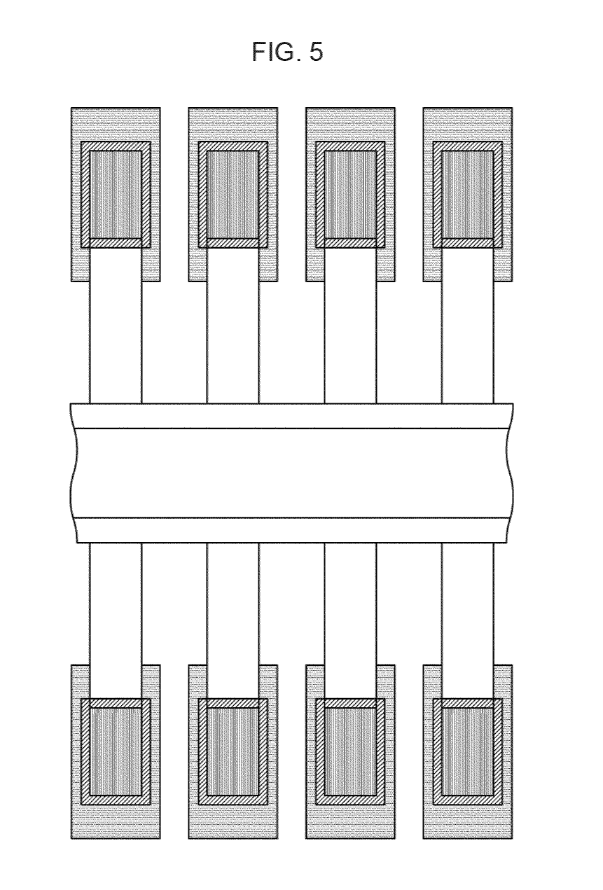

FIG. 4 shows a schematic configuration of a top surface of the printed circuit board 1. The signal pin 3 of the surface mount connector 2 is connected to the signal pin pad 5 via the soldered joint portion 9 and the fillet 10. The cut-out portion 11 is provided at a central part of the signal pin pad 5 as illustrated in FIG. 2. The cut-out portion 11 is rectangular as shown in the drawing.

Moreover, the ground pin 4 is connected to the ground pin pad 6 via the soldered joint portion 12 and the fillet 13.

Furthermore, as illustrated in FIG. 4. J represents the length of the soldered joint portion 9 and K represents the length of the cut-out portion 11.

When L2 represents size tolerance of the signal pin 3 in its lengthwise direction. M2 represents fabrication tolerance of the printed circuit board 1 in its lengthwise direction, and N2 represents mount position tolerance of the surface mount connector 2 in its lengthwise direction under the above-described circumstance, variations of tolerances are usually normal distribution and the sum of the tolerances can be expressed by the sum of squares of tolerance elements. So, the length K of the cut-out portion 11 according to this embodiment is set within the range satisfying the following Formula (2).

[Math. 2]

K<J−\sqrt{L2²+M2²+N2²} (2)

By setting the length K of the cut-out portion 11 within the range satisfying the above Formula (2), the fillet 10 can be formed in the same manner as in the conventional case around the joint portion between the signal pin 3 and the signal pin pad 5 which have been soldered. Joint reliability with aged degradation of the soldered joint portion 9 which is connected by soldering is decided depending on the area where the fillet 10 is formed. Since the area where the fillet 10 is formed is secured in this embodiment in the same manner as in the conventional case, the same degree of joint reliability between the signal pin 3 and the signal pin pad 5 as that of the conventional case can be secured.

If the center of the cut-out portion 11 is set to the center of the area where the signal pin 3 overlaps with the signal pin pad 5, based on the above Formula (2), it is possible to cut out the signal pin pad 5 most efficiently.

When the surface mount connector 2 is a general DDR connector, the width D of the signal pin 3 is 0.5 mm and the length J of the soldered joint portion 9 is 0.9 mm. If size tolerances L1 and L2 of the signal pin 3 are ±0.05 mm, fabrication tolerances M1and M2 of the printed circuit board 11 are ±0.05 mm, and mount position tolerances N1 and N2 of the surface mount connector 21 are ±0.05 mm, the maximum width E to cut out the signal pin pad 5 according to the above Formula (1) can be 0.41 mm and the maximum length K to cult out the signal pin pad 5 according to the above Formula (2) can be 0.81 mm.

FIG. 5 shows a schematic configuration of the top surface of the conventional printed circuit board as compared to the schematic configuration of the top surface of the printed circuit board 1 illustrated in FIG. 4. The cut-out portion 11 according to this embodiment is not provided in the conventional printed circuit board. So, the impedance of the signal pin pads decreases due to capacitive coupling between the signal pin pads and the ground layer as explained with reference to FIG. 3. As a result, a problem of signal quality degradation occurs due to impedance unmatching between the signal pins and the signal pin pads.

### (1-4) Simulation Results

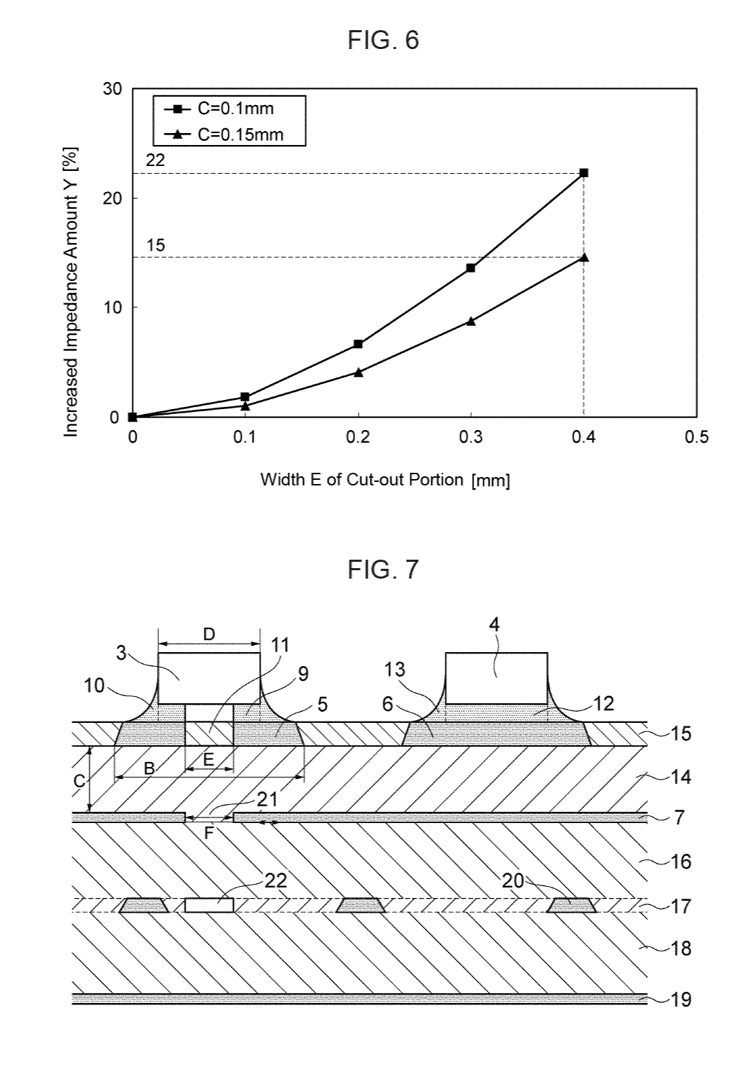

FIG. 6 shows simulation results in this embodiment. Regarding the simulation, the width B of the signal pin pad 5 is set to 0.7 mm, the width D of the signal pin 3 is set to 0.5 mm, the thickness C of the surface insulating layer 14 is set to 0.1 mm and 0.15 mm, and the width E of the cut-out portion 11 is set to 0 to 0.4 mm; and an increased impedance amount Y according to this embodiment as compared to the conventional impedance was calculated by setting the same conditions except for the existence of the cut-out portion 11. As a result, the increased impedance amount Y is calculated as an approximate value according to the following Formula (3).

$$\begin{matrix}[ Math . 3 ] & \\ Y = 14 \frac{{E}^{2}}{C} & ( 3 )\end{matrix}$$

According to the above Formula (3) and the simulation results of FIG. 6, for example, when the width E of the cut-out portion 11 is 0.4 mm and the thickness C of the surface insulating layer 14 is 0.1 to 0.15 mm, the increased impedance amount Y increases by 15% to 22% as compared to the conventional case.

### (1-5) Advantageous Effects of First Embodiment

With the printed circuit board 1 according to this embodiment as explained above, it is possible to prevent the capacitive coupling between the signal pin pad 5 and the ground layer 7 and prevent the impedance reduction of the signal pin pad 5 by providing the cut-out portion 11. Furthermore, it is possible to secure the area to form the fillet 10 by setting the size of the cut-out portion 11 as an appropriate size. Therefore, according to this embodiment, it is possible to prevent the impedance reduction of the signal pin pad 5 and secure joint reliability between the signal pin 3 and the signal pin pad 5.

### (2) Second Embodiment

The difference between a printed circuit board according to a second embodiment and the printed circuit board 1 according to the first embodiment is that a chipped-off portion is provided in part of a ground layer for the printed circuit board according to the second embodiment. The same configuration as that of the first embodiment is given the same reference numeral as in the first embodiment, an explanation about it has been omitted, and any different configuration will be explained.

### (2-1) Cross-Section Surface Configuration of Printed Circuit Board

FIG. 7 shows a schematic configuration of cross-section surface A of the printed circuit board 1. The ground layer 7 which is a first layer is provided with a chipped-off portion 21. The position of the chipped-off portion 21 is set to directly below the cut-out portion 11. A non-wirable area 22 is located in a signal layer 17 directly below the position of the chipped-off portion 21. If a signal line 20 is located in the non-wirable area 22, a signal return current cannot be secured, thereby causing signal quality degradation. If the width F of the chipped-off portion 21 is set as a large width, the width of the non-wirable area 22 also increases and a wiring area of the signal layer 17 decreases. Therefore, the width F of the chipped-off portion 21 should preferably be set as small as possible.

### (2-2) Top Surface Configuration of Printed Circuit Board

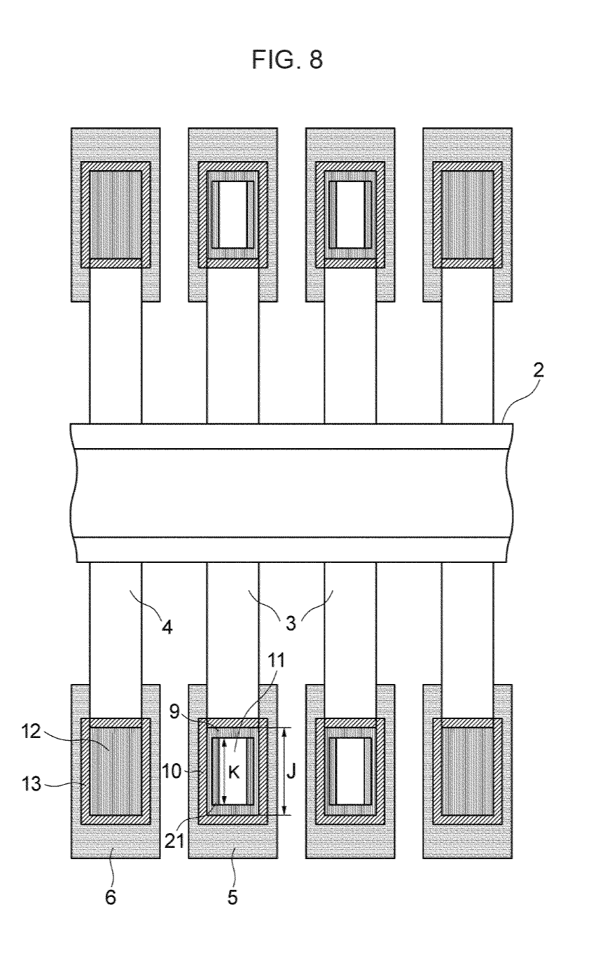

FIG. 8 shows a schematic configuration of a top surface of the printed circuit board 1. The chipped-off portion 21 is provided directly below the signal pin pad 5 as illustrated in FIG. 7.

### (2-3) Simulation Results

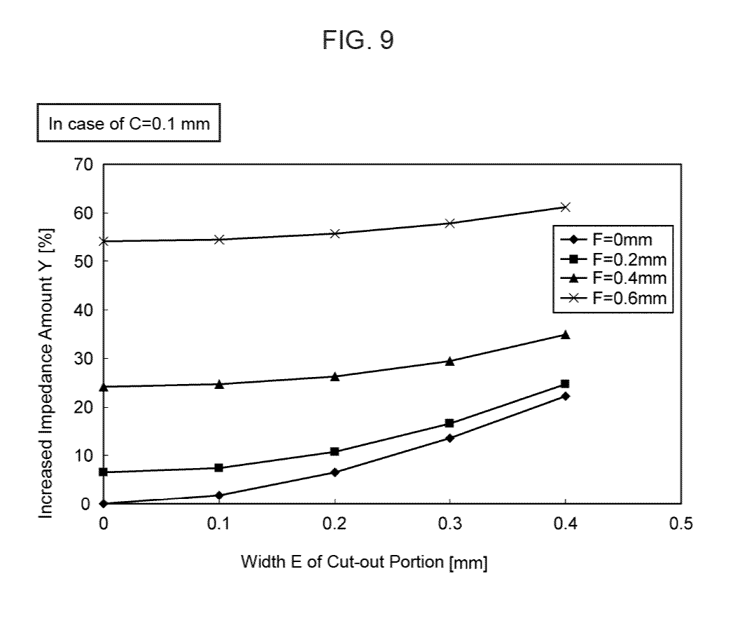

FIG. 9 shows simulation results in this embodiment. Regarding the simulation, the width B of the signal pin pad 5 is set to 0.7 mm, the width D of the signal pin 3 is set to 0.5 mm, the thickness C of the surface insulating layer 14 is set to 0.1 mm, the width E of the cut-out portion 11 is set to 0 to 0.4 mm, and the width F of the chipped-off portion 21 is set to 0 to 0.6 mm; and an increased impedance amount Y according to this embodiment as compared to the conventional impedance was calculated by setting the same conditions except for the existence of the cut-out portion 11 and the existence of the chipped-off portion 21.

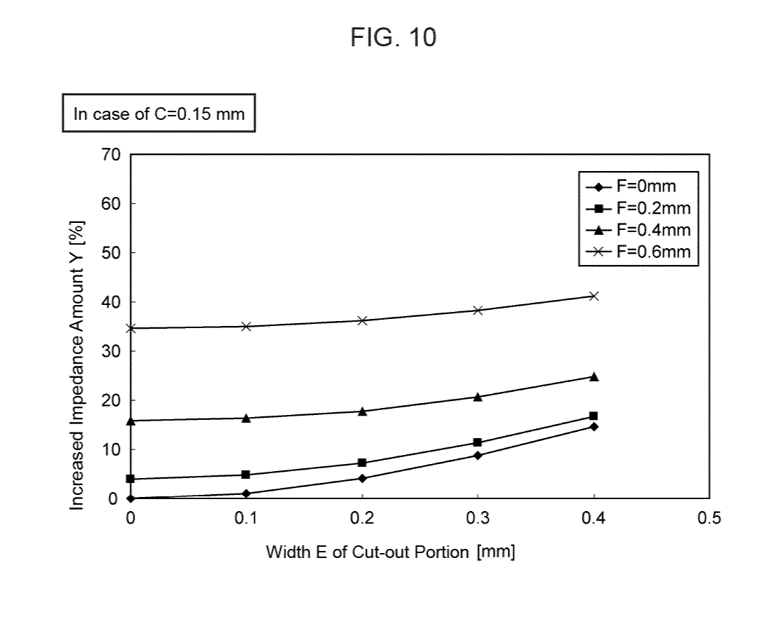

FIG. 10 shows simulation results in this embodiment in the same manner as in FIG. 9. Regarding the simulation, the increased impedance amount Y was calculated by conducting the same simulation as that of FIG. 9, except that the thickness C of the surface insulating layer 14 was changed to 0.15 mm.

The increased impedance amount Y is calculated as an approximate value according to the following Formula (4) based on the simulation results of FIG. 9 and FIG. 10.

$$\begin{matrix}[ Math . 4 ] & \\ Y = 14 \frac{( {E}^{2} + {F}^{2} )}{C} & ( 4 )\end{matrix}$$

According to the above Formula (4) and the simulation results of FIG. 9, for example, when the width E of the cut-out portion 11 is 0.4 mm, the width F of the chipped-off portion 21 is 0.2 mm, and the thickness C of the surface insulating layer 14 is 0.1 mm, the increased impedance amount Y increases by 25% as compared to the conventional case. On the other hand, if the width E of the cut-out portion 11 is changed to 0 mm and the width F of the chipped-off portion 21 is doubled and changed to 0.4 mm, the increased impedance amount Y increases by 24% as compared to the conventional case. Consequently, the width F of the chipped-off portion 21 can be limited to a half of the width F in the case where only the ground layer 7 is chipped off; and the increased impedance amount Y of the same degree can obtained by chipping off both the signal pin pad 5 and the ground layer 7, rather than chipping off only the ground layer 7. Furthermore, the smaller the width F of the chipped-off portion 21 is, the larger the increased impedance amount Y becomes along with the increase of the width E of the cut-out portion 11.

### (2-4) Advantageous Effects of Second Embodiment

With the printed circuit board 1 according to this embodiment as explained above, it is possible to prevent the capacitive coupling between the signal pin pad 5 and the ground layer 7 and prevent the impedance reduction of the signal pin pad 5 by providing the cut-out portion 11 and the chipped-off portion 21. Furthermore, it is possible to effectively increase the increased impedance amount Y along with the increase of the width E of the cut-out portion 11 by setting the width F of the chipped-off portion 21 as small as possible.

### (3) Third Embodiment

The difference between a printed circuit board according to a third embodiment and the printed circuit board according to a second embodiment is that a chipped-off portion in a ground layer is divided into two portions in the second embodiment. The same configuration as that of the first and second embodiments is given the same reference numeral as in the first and second embodiments, an explanation about it has been omitted, and any different configuration will be explained.

### (3-1) Cross-Section Surface Configuration of Printed Circuit Board

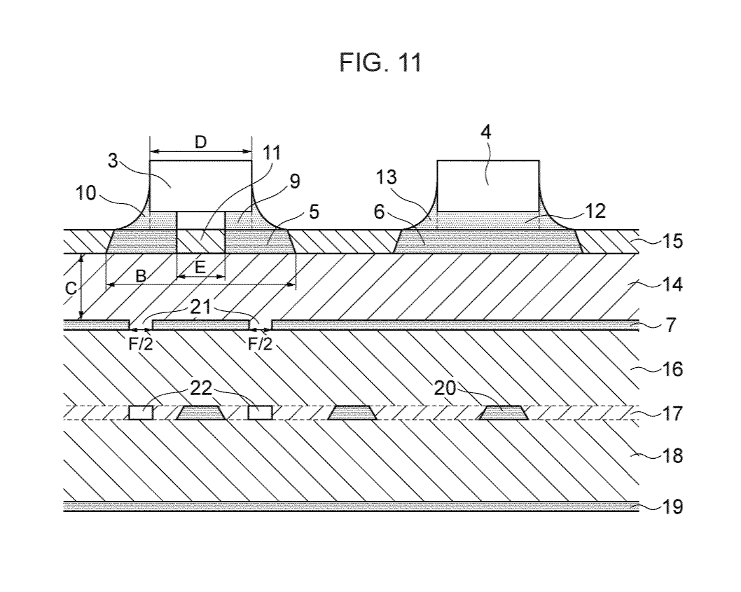

FIG. 11 shows a schematic configuration of cross-section surface A of the printed circuit board 1. The ground layer 7 which is a first layer is provided with a chipped-off portion 21. Regarding the position of the chipped-off portion 21, it is divided into two portions and their two positions are set to directly below the cut-out portion 11. The width of each of the two divided and set chipped-off portions 21 is set to a half of the width F of the chipped-off portion 21 provided in the second embodiment.

### (3-2) Top Surface Configuration of Printed Circuit Board

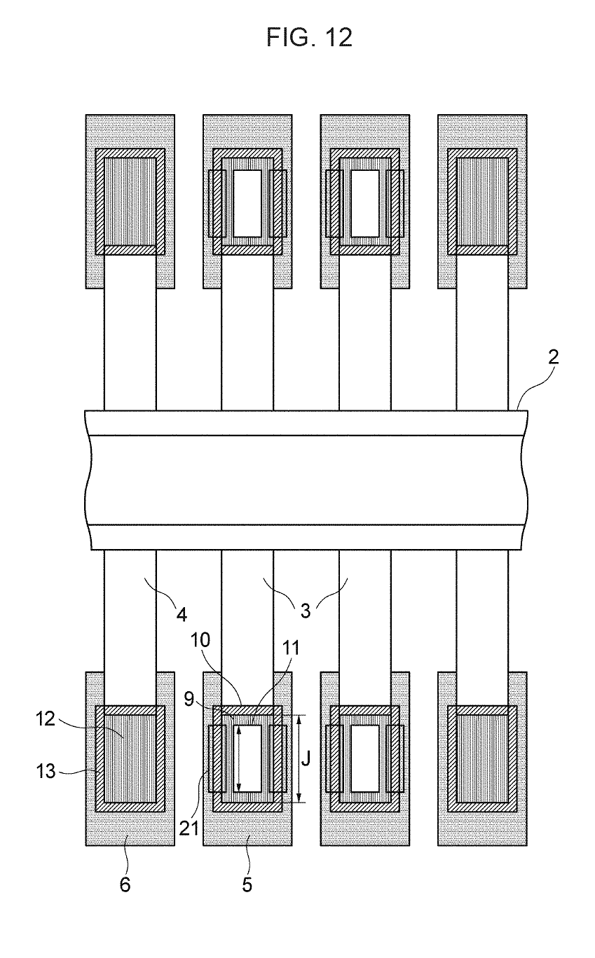

FIG. 12 shows a schematic configuration of a top surface of the printed circuit board 1. The chipped-off portions 21 are provided at two positions directly below the signal pin pad 5 as illustrated in FIG. 11.

### (3-3) Simulation Results

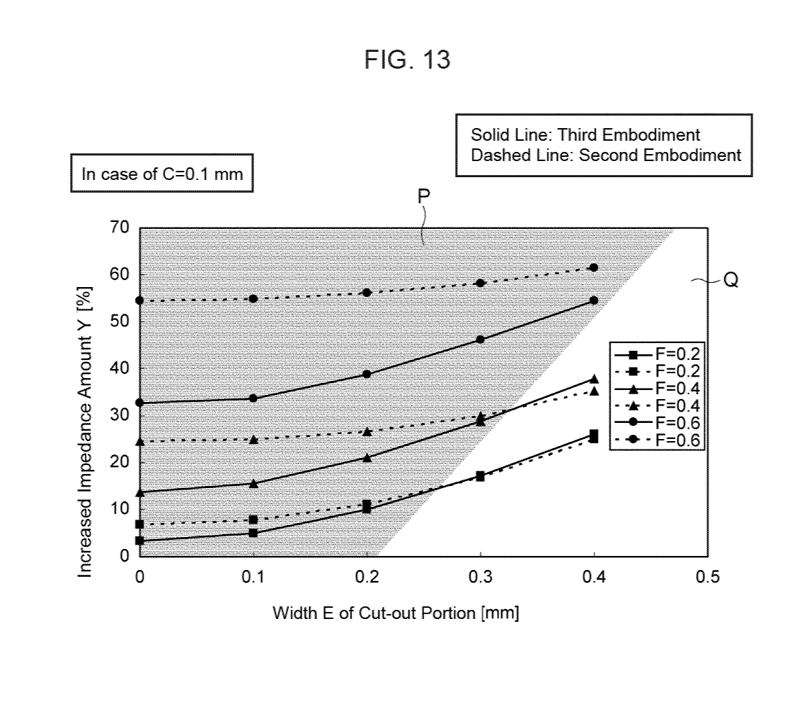

FIG. 13 shows simulation results in this embodiment. Regarding the simulation, the width B of the signal pin pad 5 is set to 0.7 mm, the width D of the signal pin 3 is set to 0.5 mm, the thickness C of the surface insulating layer 14 is set to 0.1 mm, the width E of the cut-out portion 11 is set to 0 to 0.4 mm, and the width F of the chipped-off portion 21 is set to 0 to 0.6 mm; and an increased impedance amount Y according to this embodiment as compared to the conventional impedance was calculated by setting the same conditions except for the existence of the cut-out portion 11 and the existence of the chipped-off portion 21. Also, the increased impedance amount Y according to the second embodiment was calculated. A solid line represents the increased impedance amount Y according to this embodiment (third embodiment) and a dashed line represents the increased impedance amount Y according to the second embodiment.

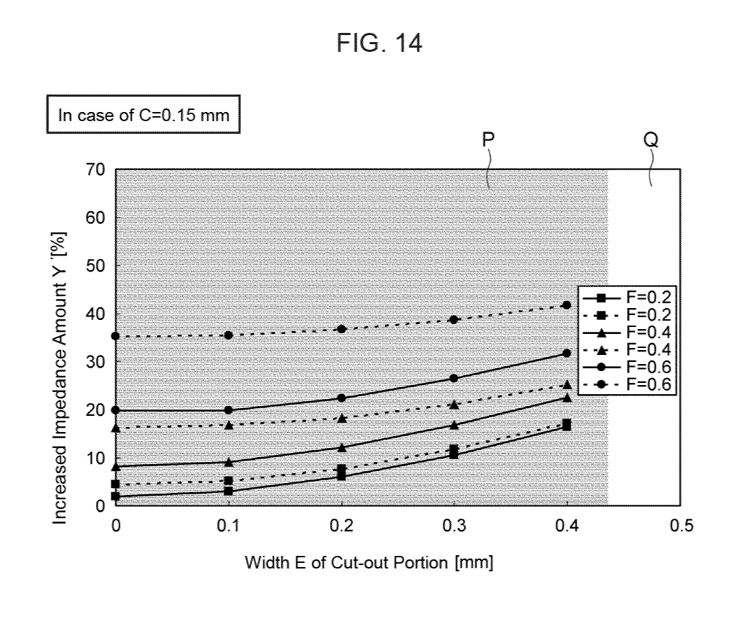

FIG. 14 shows simulation results in this embodiment in the same manner as in FIG. 13. Regarding the simulation, the increased impedance amount Y was calculated by conducting the same simulation as that of FIG. 13, except that the thickness C of the surface insulating layer 14 was changed to 0.15 mm.

Referring to FIG. 13 and FIG. 14, area P is an area where the increased impedance amount Y in the second embodiment is larger than the increased impedance amount Y in the third embodiment; and area Q is an area where the increased impedance amount Y in the third embodiment is larger than the increased impedance amount Y in the second embodiment.

According to the simulation results in FIG. 13 and FIG. 14, the range of the width F of the chipped-off portion 21 within which the increased impedance amount Y in the third embodiment becomes larger than the increased impedance amount Y in the second embodiment is calculated according to the following Formula (5).

[Math. 5]

F<2E−C+0.7 (5)

According to the above Formula (5) and the simulation results of FIG. 13 and FIG. 14, the impedance of the signal pin pad 5 can be effectively increased by adopting the chipped-off portion 21 according to the third embodiment within the range satisfying the above Formula (5) and adopting the chipped-off portion 21 according to the second embodiment outside of the range of the above Formula (5).

### (3-4) Advantageous Effects of Third Embodiment

With the printed circuit board 1 according to this embodiment as explained above, it is possible to prevent the capacitive coupling between the signal pin pad 5 and the ground layer 7 and prevent the impedance reduction of the signal pin pad 5 by providing the cut-out portion 11 and the chipped-off portions 21. Furthermore, it is possible to effectively increase the increased impedance amount Y by setting the positions and range of the chipped-off portions 21 to appropriate positions and range according to the width E of the cut-out portion 11 and the thickness C of the surface insulating layer 14.

### REFERENCE SIGNS LIST

1 printed circuit board
2 surface mount connector
3 signal pin
4 ground pin
5 signal pin pad
6 ground pin pad
7, 19 ground layers
8 signal line
9, 12 soldered joint portions
10, 13 fillets
11 cut-out portion
14 surface insulating layer
15 resist layer
16, 18 intermediate insulating layers
17 signal layer
20 signal line
21 chipped-off portion
22 non-wirable area
A cross-section surface
B width of signal pin pad
C thickness of surface insulating layer
D width of signal pin
E width of cut-out portion
F width of chipped-off portion
G width of signal line
J length of soldered joint portion
K length of cut-out portion

1. A printed circuit board comprising:
a signal pin pad soldered to a signal pin from a surface mount connector; and
a ground layer located as a lower layer below the signal pin pad,
wherein a fillet is formed around a joint area between the signal pin and the signal pin pad after soldering; and
wherein a cut-out portion is provided in the signal pin pad within a joint area connected with the signal pin; and
wherein the size of the cut-out portion is set within the range of being completely covered within the joint area with the signal pin based on size tolerance of the signal pin, fabrication tolerance of the printed circuit board, and mount position tolerance of the surface mount connector.

2. The printed circuit board according to claim 1, wherein regarding the size of the cut-out portion,
a value smaller than a value obtained by subtracting a square root of a sum of squares of each of size tolerance of the signal pin in its widthwise direction, fabrication tolerance of the printed circuit board in its widthwise direction, and mount position tolerance of the surface mount connector in its widthwise direction from the width of the signal pin is set as the width of the cut-out portion, and
a value smaller than a value obtained by subtracting a square root of a sum of squares of each of size tolerance of the signal pin in its lengthwise direction, fabrication tolerance of the printed circuit board in its lengthwise direction, and mount position tolerance of the surface mount connector in its lengthwise direction from the length of the joint area is set as the length of the cut-out portion.

3. The printed circuit board according to claim 1, wherein the ground layer is provided with a chipped-off portion; and
the chipped-off portion is located directly below the cut-out portion.

4. The printed circuit board according to claim 1, wherein the ground layer is provided with a chipped-off portion; and
the chipped-off portion is divided and located at two positions on both sides of an area directly below the cut-out portion.
